(19) United States
(12) Patent Application Publication
(10) Pub. No.: US 2025/0244681 A1
(43) Pub. Date: Jul. 31, 2025

(54) ELECTRONIC DEVICE AND METHOD OF OPERATION THEREOF

(71) Applicant: Samsung Electronics Co., Ltd., Suwon-si (KR)

(72) Inventors: Chulho JUNG, Suwon-si (KR); Jaewon YANG, Suwon-si (KR); Jungmin KIM, Suwon-si (KR); Sang Chul YEO, Suwon-si (KR); Hyeok LEE, Suwon-si (KR)

(73) Assignee: Samsung Electronics Co., Ltd., Suwon-si (KR)

(21) Appl. No.: 18/968,290

(22) Filed: Dec. 4, 2024

(30) Foreign Application Priority Data
Jan. 31, 2024 (KR) 10-2024-0015363

(51) Int. Cl. G03F 7/00; G03F 1/36

(52) U.S. Cl. CPC G03F 7/705; G03F 1/36; G03F 7/70441

(57) ABSTRACT

Provided are an electronic device and a method of an operation thereof. The electronic device includes a memory and processing circuitry configured to execute the instructions stored in the memory to cause the electronic device to acquire a first input image based on an image of a design pattern to be formed on a wafer, transform the first input image into a second input image based on a factor not affecting a process of manufacturing a semiconductor device, and train a process simulation model by using a pair of the first input image and the second input image.

### CROSS-REFERENCE TO RELATED APPLICATION

This application claims priority to and the benefit of Korean Patent Application No. 10-2024-0015363 filed in the Korean Intellectual Property Office on Jan. 31, 2024, the entire contents of which are incorporated herein by reference.

### BACKGROUND

### (a) Field of the Invention

The present disclosure relates to electronic devices and methods of an operation thereof.

### (b) Description of the Related Art

In the exposure process or etching process of manufacturing a semiconductor device, a design pattern and an actual pattern formed on a wafer may be different from each other, for example, due to a diffraction effect or a process effect. Optical proximity correction (OPC) technology and process proximity correction (PPC) technology are being developed to predict this error and correct a mask pattern for the design pattern to be formed on the wafer. Therefore, there is a need for a simulation model which may accurately simulate the corresponding process.

### SUMMARY

Some example embodiments of the present disclosure provide electronic devices which could alleviate or prevent overfitting of a process simulation model and improve robustness of the process simulation model.

According to an example embodiment, an electronic device may include a memory configured to store instructions, and processing circuitry configured to execute the instructions stored in the memory to cause the electronic device to acquire a first input image based on an image of a design pattern to be formed on a wafer, transform the first input image into a second input image based on a factor not affecting a process of manufacturing a semiconductor device, and train a process simulation model by using a pair of the first input image and the second input image.

According to an example embodiment, an electronic device may include memory, and processing circuitry configured to execute the instructions stored in the memory to cause the electronic device to acquire a first input image based on an image of a design pattern to be formed on a wafer, transform the first input image into a second input image based on a factor not affecting a process of manufacturing a semiconductor device, acquire a pair of output images by inputting a pair of the first input image and the second input image into a process simulation model, and train the process simulation model to reduce a value of a first loss function based on a difference between one of the pair of output images and an image of an actual pattern formed on the wafer and a value of a second loss function based on a difference between the pair of the output images.

According to an example embodiment, a method of an operation of an electronic device may include an operation of acquiring a first input image based on an image of a design pattern to be formed on a wafer; an operation of transforming the first input image into a second input image based on a factor not affecting a process of manufacturing a semiconductor device; and an operation of training a process simulation model by using a pair of the first input image and the second input image.

As set forth above, according to some example embodiments of the present disclosure, it is possible to alleviate or prevent overfitting of the simulation model and improve the robustness of the process simulation model.

### BRIEF DESCRIPTION OF THE DRAWINGS

FIG. 1 is a block diagram of an electronic device according to an example embodiment.

FIG. 2 is a flowchart showing a method of an operation of an electronic device according to an example embodiment.

FIG. 3 is a diagram showing a method of the electronic device to train a process simulation model according to an example embodiment.

FIG. 4 is a diagram showing a method of the electronic device to transform an input image according to an example embodiment.

FIG. 5 is a diagram showing a method of the electronic device to inversely transform an output image according to an example embodiment.

FIG. 6 is a diagram showing a method of the electronic device to train the process simulation model according to an example embodiment.

FIG. 7 is a diagram showing an example of a computer device implementing the electronic device according to an example embodiment.

### DETAILED DESCRIPTION

Hereinafter, some example embodiments of the present disclosure are described in detail with reference to the accompanying drawings for those skilled in the art to easily practice the present disclosure. However, the present disclosure may be implemented in various different forms and is not limited to the example embodiments described herein.

A portion unrelated to the description is omitted in order to obviously describe the present disclosure, and the same or similar components are denoted by the same reference numeral throughout the specification.

In addition, the size and thickness of each component shown in the accompanying drawings are arbitrarily shown for convenience of explanation, and therefore, the present disclosure is not necessarily limited to contents shown in the drawings. The thicknesses are exaggerated in the drawings in order to clearly represent several layers and regions. In addition, the thicknesses of some layers and regions are exaggerated in the drawings for convenience of explanation.

In addition, when an element such as a layer, a film, a region, or a substrate is referred to as being “on” or “above” another element, the element may be “directly on” another element or may have a third element interposed therebetween. On the other hand, when an element is referred to as being “directly on” another element, there is no third element interposed therebetween. In addition, when an element is referred to as being “on” or “above” a reference element, the element may be disposed on or below the reference element, and may not necessarily be “on” or “above” the reference element in an opposite direction of gravity.

In addition, throughout the specification, unless described to the contrary, “including” any component is to be understood to imply the inclusion of other elements rather than the exclusion of other elements.

In addition, throughout the specification, an expression “on a plane” may indicate a case where a target is viewed from the top, and an expression “on a cross-section” may indicate a case where a cross-section of the target taken along a vertical direction is viewed from its side.

In addition, the terms “part”, “˜er/or”, “module”, and the like, described in the specification may indicate a unit of processing at least one function or operation, and may be implemented by hardware, software, or a combination of hardware and software. In addition, a plurality of “parts”, a plurality of “˜ers/ors”, or a plurality of “modules” may be integrated in at least one module and implemented by at least one processor except for a “part”, an “˜er/or”, or a “module” that needs to be implemented by specific hardware.

In the specification, “transmission” or “provision” may include not only direct transmission or provision, but also indirect transmission or provision through another device or using a bypass path.

A term of a singular number in the specification may be interpreted as the singular number or its plural number unless explicitly expressed such as “one” or “single.”

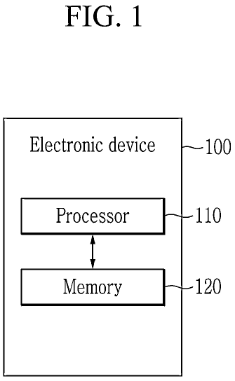

Hereinafter, an electronic device according to an example embodiment is described with reference to FIG. 1.

The electronic device according to an example embodiment may train an image-based deep learning model simulating a process of manufacturing a semiconductor device by processing a wafer (e.g., exposure process or etching process), and predict a process result based on the trained model. For example, a mask pattern and a pattern formed on the wafer may be different from each other in the exposure process or the etching process. That is, the design pattern and actual pattern of the wafer may be different from each other, thus requiring the process simulation model capable of accurately predicting the actual pattern based on the design pattern. The process simulation model may be used to predict and correct a process defect.

FIG. 1 is a block diagram of the electronic device according to an example embodiment.

Referring to FIG. 1, an electronic device 100 according to an example embodiment may include a processor 110 and a memory 120. In some example embodiments, the electronic device 100 may further include another component (e.g., communication circuit).

The processor 110 may be operatively connected to the memory 120. The processor 110 may execute instructions stored in the memory 120. The processor 110 may execute the instructions stored in the memory 120 to allow the electronic device 100 to perform operations described below. The operations described below as being performed by the processor 110 may be performed by the processor 110 and/or at least one another component of the electronic device 100 that is connected to the processor 110. Therefore, it may be understood that the operations are performed by the electronic device 100.

The processor 110 may acquire a first input image based on an image of the design pattern to be formed on the wafer. The image of the design pattern may be an image in which a design engineer of the semiconductor device designs a circuit pattern to be formed on the wafer. The design pattern may include, for example, an exposure mask pattern or an etch mask pattern. The image of the design pattern may be stored in the memory 120. For example, the image of the design pattern may be received by the electronic device 100 from an external electronic device and stored in the memory 120.

The processor 110 may acquire the first input image by augmenting the image of the design pattern. For example, the image of the design pattern may be an image corresponding to one wafer. The processor 110 may randomly crop some regions of the image of the design pattern to a specified size. The processor 110 may acquire a plurality of cropped images from the image of one image of the design pattern. The processor 110 may rotate or flip each of the cropped images to generate a plurality of augmented images from one cropped image. The plurality of augmented images generated from one image of the design pattern may be used as input data to train the process simulation model. The processor 110 may acquire the plurality of first input images by augmenting one image of the design pattern. The processor 110 may acquire the plurality of first input images corresponding to each image of the plurality of design patterns.

As described above, the electronic device 100 may increase an amount of training data by acquiring the plurality of first input images from one image of the design pattern, thus improving performance of the process simulation model which is a training target.

The processor 110 may transform the first input image into a second input image based on a factor not affecting the process. The factor not affecting the process may include at least one of the translation, rotation, or flip of the design pattern. For example, in a certain process, a result (Result 1) of the process being performed while the design pattern is moved in an x-axis direction and/or a y-axis direction may be substantially the same as a result (Result 2) of the process being performed while the design pattern is not moved. Here, the fact that the process results are substantially the same as each other may indicate that Result 2 matches Result 1 when Result 2 is translated in the same way as the design pattern is translated. For example, in a certain process, a result (Result 1) of the process being performed while the design pattern is rotated by 90°, 180°, and/or 270° may be substantially the same as a result (Result 2) of the process being performed while the design pattern is not rotated. Here, the fact that the process results are substantially the same as each other may indicate that Result 2 matches Result 1 when Result 2 is rotated in the same way as the design pattern is rotated. For example, in a certain process, a result (Result 1) of the process being performed while the design pattern is horizontally and/or vertically flipped may be substantially the same as a result (Result 2) of the process being performed while the design pattern is not flipped. Here, the fact that the process results are substantially the same as each other may indicate that Result 2 matches Result 1 when Result 2 is flipped in the same way as the design pattern is flipped. The transformation of this design pattern may be the factor not affecting the process when the process result of the untransformed design pattern and the process result of the transformed design pattern are substantially the same as each other even though the design pattern is transformed by the translation, the rotation, and/or the flip.

The factor not affecting the process may be different for each process. For example, in a certain process, the translation or rotation of the design pattern may not affect the process, while the flip may affect the process. For another example, in a certain process, the rotation of 180° may not affect the process, while the rotation of 90° or the rotation of 270° may affect the process. These factors are only examples, and the factor not affecting the process may be different for each process.

The processor 110 may acquire the second input image by performing at least one transformation of the translation, the rotation, or the flip on the pattern included in the first input image. The translation may include, for example, a movement of the pattern in the x-axis direction and/or the y-axis direction, and is not limited thereto. The rotation may include, for example, the rotation of 90°, the rotation of 180°, and/or the rotation of 270°, is not limited thereto, and may include rotations of various other angles. The flip may include, for example, the horizontal flip and/or the vertical flip, and is not limited thereto. The processor 110 may acquire the second input image by performing at least one transformation corresponding to factor(s) not affecting the process among the various types of transformations described above. For example, in a certain process, when the x-axis movement, y-axis movement, and rotation of 180° of the design pattern do not affect the process, the processor 110 may acquire the second input image including the pattern included in the first input image, which is moved by x1 in the x-axis direction, moved by y1 in the y-axis direction, and rotated by 180°.

When the plurality of transformations correspond to the factors not affecting the process, the processor 110 may perform only some of these factors. For example, in a certain process, when the x-axis movement, y-axis movement, and rotation of 180° of the design pattern do not affect the process, the processor 110 may acquire the second input image including the pattern included in the first input image, which is rotated by 180°.

The processor 110 may train the process simulation model by using a pair of the first input image and the second input image. The process simulation model is a deep learning model simulating the process based on the image, and may predict the actual pattern formed on the wafer by inputting the image of the design pattern to be formed on the wafer, and output an image of the predicted actual pattern. The processor 110 may acquire a pair of a first output image corresponding to the first input image and a second output image corresponding to the second input image by inputting the pair of the first and second input images into the process simulation model.

The processor 110 may train the process simulation model based on a difference between the first output image and the image of the actual pattern formed on the wafer. The image of the actual pattern formed on the wafer may be an image acquired by measuring the actual pattern formed on the wafer as a result of performing the process based on the design pattern corresponding to the first input image. The image acquired by measuring the actual pattern may be stored in the memory 120. For example, the image acquired by measuring the actual pattern may be received by the electronic device 100 from the external electronic device (e.g., measuring instrument) and stored in the memory 120. As described above, the first input image may be the image acquired by augmenting the image of the design pattern. Accordingly, the image of the actual pattern to be compared may be an augmented image of the image acquired by measuring the actual pattern. For example, the image of the actual pattern may be an image acquired by cropping, rotating, and/or flipping the image acquired by measuring the actual pattern.

The processor 110 may train the process simulation model to reduce a value of a first loss function based on the difference between the first output image and the image of the actual pattern.

As described above, the process result of the design pattern corresponding to the second input image may be substantially the same as the process result of the design pattern corresponding to the first input image. The process result may correspond to output data of the process simulation model, and the first output image corresponding to the first input image and the second output image corresponding to the second input image may thus be substantially the same as each other. Accordingly, the processor 110 may train the process simulation model based on a difference between the first output image and the second output image in addition to the difference between the first output image and the image of the actual pattern.

The second output image is output data corresponding to the second input image acquired by transforming the first input image. Therefore, the first output image and the second output image may also have the same relationship as the transformation relationship between the first input image and the second input image. According to an example embodiment, the processor 110 may inversely transform the second output image. The processor 110 may inversely transform the second output image by reversing the transformation from the first input image to the second input image. The processor 110 may compare the first output image with the inversely transformed second output image. However, example embodiments are not limited thereto. In some example embodiments, the processor 110 may acquire the transformed first output image by performing the same transformation as the transformation from the first input image to the second input image on the first output image. Here, the processor 110 may compare the transformed first output image with the second output image.

According to an example embodiment, the processor 110 may train the process simulation model based on the difference between the first output image and the image of the actual pattern and a difference between the first output image and the inversely transformed second output image. The processor 110 may train the process simulation model to reduce the value of the first loss function based on the difference between the first output image and the image of the actual pattern and a value of a second loss function based on the difference between the first output image and the inversely transformed second output image.

For example, the processor 110 may train the process simulation model to reduce the sum of the value of the first loss function and the value of the second loss function. For example, the processor 110 may train the process simulation model to minimize the sum of the value of the first loss function and the value of the second loss function. Training the process simulation model may indicate adjusting its parameters to reduce the value of the loss function of the process simulation model.

The loss function for training the process simulation model may further include a loss function related to another loss in addition to the first loss function and the second loss function described above. The processor 110 may calculate the sum of the plurality of loss functions by multiplying the plurality of loss functions by a ratio for each loss function. For example, the processor 110 may calculate the sum of the first loss function and the second loss function by adding a value acquired by multiplying the value of the first loss function by the ratio corresponding to the first loss function and a value acquired by multiplying the value of the second loss function by the ratio corresponding to the second loss function.

The processor 110 may generate a plurality of mini-batches by randomly sampling the pair of the input images. The processor 110 may generate the plurality of mini-batches by randomly extracting a specified number of pairs of the input images several times from the plurality of pairs of the input images each including the first input image and the second input image transformed from the first input image. The processor 110 may train the process simulation model by using the plurality of mini-batches. The processor 110 may train the process simulation model in a mini-batch unit. For example, the processor 110 may extract n pairs of the input images m times from all the pairs of the input images and generate m mini-batches of size n. The processor 110 may train the process simulation model in the mini-batch unit, and update the process simulation model whenever completing its learning for each mini-batch. The processor 110 may train the process simulation model in the mini-batch unit to thus allow the process simulation model to have an improved learning robustness, by learning a more general pattern, having an improved learning speed, and having a reduced influence of noise.

The processor 110 may predict the process result based on the trained process simulation model. The processor 110 may acquire the output image corresponding to the actual pattern predicted to be formed on the wafer by performing the process based on the design pattern by inputting the input image acquired from the image of the design pattern into the trained process simulation model.

The electronic device 100 according to an example embodiment may alleviate or prevent overfitting of the process simulation model by training the process simulation model based on the first input image, and further based on the second input image acquired by transforming the first input image based on the factor not affecting the process.

The electronic device 100 according to an example embodiment may input the pair of the first and second input images into the process simulation model to thus train the process simulation model based on the difference between the first output image corresponding to the first input image and the image of the actual pattern, and further based on the difference between the second output image corresponding to the second input image and the first output image.

According to an example embodiment, the electronic device 100 may separately input the first input image and the second input image into the process simulation model to thus train the process simulation model based on the difference between the first output image corresponding to the first input image and the image of the actual pattern, and improve the robustness of the process simulation model compared to a comparative example of training the process simulation model based on the difference between the second output image corresponding to the second input image and the image of the actual pattern.

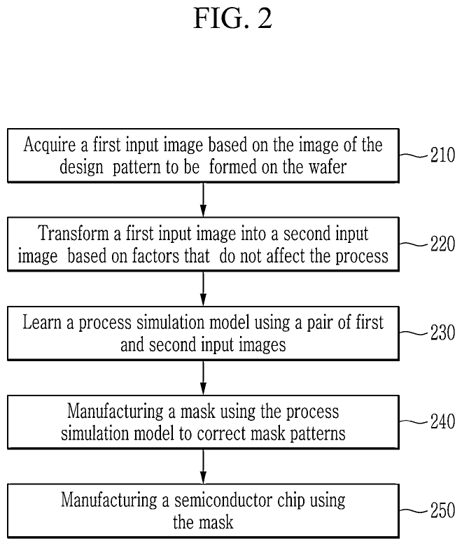

Hereinafter, the description describes a method of an operation of an electronic device according to an example embodiment with reference to FIG. 2.

FIG. 2 is a flowchart showing the method of an operation of an electronic device according to an example embodiment. The operations described below may be performed by the electronic device 100 of FIG. 1.

In operation 210, the electronic device may acquire the first input image based on the image of the design pattern to be formed on the wafer. The electronic device may acquire the first input image by augmenting the image of the design pattern. For example, the electronic device may acquire the first input image by cropping, rotating, and/or flipping the image of the design pattern.

In operation 220, the electronic device may transform the first input image into the second input image based on the factor not affecting the process. The factor not affecting the process may include at least one of the translation, rotation, or flip of the design pattern. The factor not affecting the process may be different for each process. The electronic device may acquire the second input image by performing, on the pattern included in the first input image, at least one transformation of the translation, the rotation, or the flip corresponding to the factor not affecting the process.

In operation 230, the electronic device may train the process simulation model by using the pair of the first and second input images. The process simulation model is the image-based deep learning model, and may receive the image corresponding to the design pattern and output the image corresponding to the predicted actual pattern. The electronic device may acquire the pair of the first output image corresponding to the first input image and the second output image corresponding to the second input image by inputting the pair of the first and second input images into the process simulation model.

The electronic device may inversely transform the second output image. The electronic device may inversely transform the second output image by reversing the transformation from the first input image to the second input image.

The electronic device may acquire the image of the actual pattern by augmenting the image acquired by measuring the wafer on which the process is performed based on the design pattern. The electronic device may acquire the image of the actual pattern by augmenting the image acquired by measuring the wafer in the same way as an augmentation method of acquiring the first input image from the image of the design pattern.

The electronic device may train the process simulation model based on the difference between the first output image and the image of the actual pattern and the difference between the first output image and the inversely transformed second output image. The electronic device may train the process simulation model to reduce the value of the first loss function based on the difference between the first output image and the image of the actual pattern and the value of the second loss function based on the difference between the first output image and the inversely transformed second output image. For example, the electronic device may train the process simulation model to minimize the sum of the value of the first loss function and the value of the second loss function. For example, the electronic device may train the process simulation model to minimize the sum of the value acquired by multiplying the value of the first loss function by the ratio corresponding to the first loss function and the value acquired by multiplying the value of the second loss function by the ratio corresponding to the second loss function.

The electronic device may generate the plurality of mini-batches by randomly sampling the pairs of the input images. The electronic device may generate the mini-batches by randomly extracting a specified number of pairs of the input images from the plurality of pairs of the input images each including the first input image and the second input image. The electronic device may perform the random sampling several times to thus generate the plurality of mini-batches.

The electronic device may train the process simulation model by using the plurality of generated mini-batches. The electronic device may train the process simulation model in the mini-batch unit. The electronic device may update the parameters of the process simulation model each time the model completes its learning for each mini-batch.

In operation 240, a mask may be manufactured using the aforementioned process simulation model to correct mask patterns. In operation 250, a semiconductor chip may be manufactured using the mask.

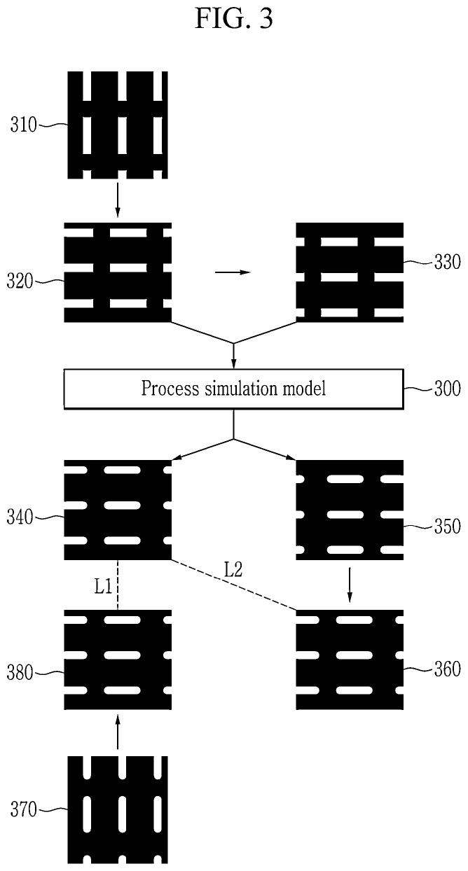

Hereinafter, the description describes a method of the electronic device to train the process simulation model according to an example embodiment with reference to FIG. 3.

FIG. 3 is a diagram showing the method of the electronic device to train the process simulation model according to an example embodiment. The electronic device according to an example embodiment may be the electronic device 100 of FIG. 1.

Referring to FIG. 3, the electronic device may acquire a first input image 320 by augmenting an image 310 of the design pattern to be formed on the wafer. The image 310 of the design pattern in FIG. 3 may be the image of the design pattern on one entire wafer, and indicate a region to be cropped in order to acquire the first input image 320 for convenience. For example, the electronic device may acquire the first input image 320 by cropping a region at a random location in the image 310 of the design pattern to the specified size, and rotating the same by −90° (e.g., performing the counterclockwise rotation of 90°).

The electronic device may acquire a second input image 330 by performing the transformation corresponding to the factor not affecting the process on the first input image 320. For example, the transformation corresponding to the factor not affecting the process may include at least one of the translation, the rotation, or the flip.

The electronic device may input a pair of the first and second input images 320 and 330 into a process simulation model 300. The process simulation model 300 may output a pair of the first and second output images 340 and 350. The first output image 340 may include the actual pattern predicted to be formed on the wafer when the process is performed based on the pattern included in the first input image 320. The second output image 350 may include the actual pattern predicted to be formed on the wafer when the process is performed based on the pattern included in the second input image 330.

The electronic device may acquire an inversely transformed second output image 360 by inversely performing the transformation from the first input image 320 to the second input image 330 on the second output image 350. For example, the electronic device may acquire the second input image 330 by rotating the first input image 320 by +180° (e.g., performing clockwise rotation of 180°). In this case, the electronic device may acquire the inversely transformed second output image 360 by rotating the second output image 350 by −180° (e.g., performing the counterclockwise rotation of 180°).

For example, the process may be actually performed based on the design pattern, and the actual pattern formed on the wafer may then be measured by the measuring instrument. Here, the electronic device may acquire an image 380 of the actual pattern by augmenting a measured image 370. The measured image 370 in FIG. 3 may be the image of the design pattern formed on one entire wafer, and indicate a region to be cropped in order to acquire the image 380 of the actual pattern for convenience. The electronic device may acquire the image 380 of the actual pattern in the same way as the method of augmenting the image 310 of the design pattern to acquire the first input image 320. For example, the electronic device may crop a region of the measured image 370 that corresponds to the region where the image 310 of the design pattern is cropped. For example, the electronic device may acquire the first input image 320 by cropping a partial region of the image 310 of the design pattern and then rotating the same by −90° (e.g., performing the counterclockwise rotation of 90°). In this case, the electronic device may acquire the image 380 of the actual pattern by rotating the image corresponding to the cropped region of the measured image 370 by −90° (e.g., performing the counterclockwise rotation of 90°).

The electronic device may calculate a value of a first loss function L1 based on a difference between the first output image 340 and the image 380 of the actual pattern. The electronic device may calculate a value of a second loss function L2 based on a difference between the first output image 340 and the inversely transformed second output image 360. The electronic device may train the process simulation model 300 to reduce the values of the first loss function L1 and the second loss function L2. For example, the electronic device may train the process simulation model 300 by updating the parameter of the process simulation model 300 to have a parameter value for minimizing the sum of the values of the first loss function L1 and the second loss function L2. For example, the electronic device may update the parameter of the process simulation model 300 to have the parameter value for minimizing the sum of the value of the first loss function L1 multiplied by a ratio c1 corresponding to the first loss function L1 and the value of the second loss function L2 multiplied by a ratio c2 corresponding to the second loss function L2.

The electronic device may acquire the plurality of first input images 320 by augmenting one image 310 of the design pattern, and train the process simulation model 300 by using the pairs of the input images and the image 380 of the actual pattern corresponding to the image 310 of the design pattern.

The electronic device may acquire the plurality of first input images 320 by augmenting each of the plurality of images 310 of the design pattern, and train the process simulation model 300 by using the pairs of the input images and the plurality of images 380 of the actual pattern respectively corresponding to the plurality of images 310 of the design pattern.

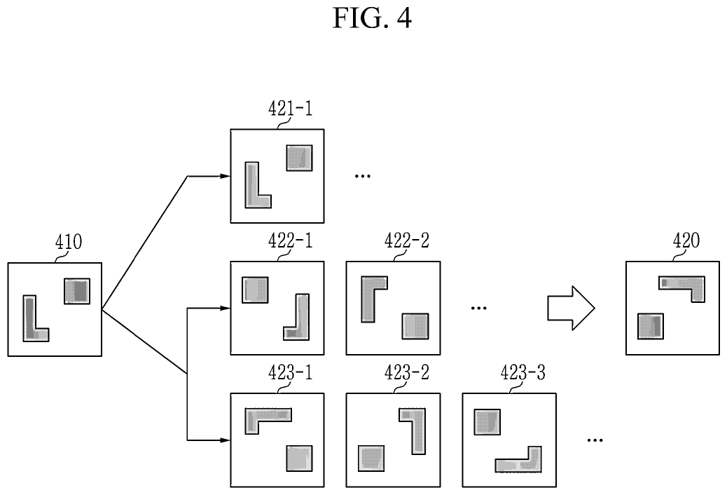

Hereinafter, the description describes a method of the electronic device to transform the input image according to an example embodiment with reference to FIG. 4.

FIG. 4 is a diagram showing the method of the electronic device to transform the input image according to an example embodiment. The electronic device according to an example embodiment may be the electronic device 100 of FIG. 1.

Referring to FIG. 4, the electronic device may generate a second input image 420 by transforming a first input image 410. The electronic device may transform the first input image 410 into the second input image 420 based on the factor not affecting the process. For example, the factor not affecting the process may include at least one of the translation, rotation, or flip of the design pattern. The translation may include, for example, the movement of the pattern in the x-axis direction and/or the y-axis direction, and is not limited thereto. The flip may include, for example, the horizontal flip or the vertical flip, and is not limited thereto. The rotation may include, for example, the rotation of 90°, the rotation of 180°, or the rotation of 270°, and is not limited thereto.

The electronic device may perform at least one transform corresponding to the factor not affecting the process among the plurality of transformations. The plurality of transformations may include, for example, first transformation 421-1 of moving the pattern in the x-axis direction or the y-axis direction, second transformation 422-1 of flipping the pattern in the horizontal direction, third transformation 422-2 of flipping the pattern in the vertical direction, fourth transformation 423-1 of rotating the pattern clockwise by 90°, fifth transformation 423-2 of rotating the pattern clockwise by 180°, and sixth transformation 423-3 of rotating the pattern clockwise by 270°, and the transformations are not limited thereto. The electronic device may acquire the second input image 420 by performing, on the pattern included in the first input image 410, at least one transformation corresponding to the factor not affecting the process among the transformations including the first transformation 421-1 to the sixth transform 423-3.

For example, the factor not affecting the process may include the movement of the pattern in the x-axis direction or y-axis direction, the clockwise rotation of 270°, and the horizontal flip. The electronic device may acquire the second input image 420 from the first input image 410 by performing the first transformation 421-1, second transformation 422-1, and sixth transformation 423-3. For example, the electronic device may acquire the second input image 420 including the pattern included in the first input image 410 that is moved by −5 in the x-axis direction and +1 in the y-axis direction, flipped horizontally, and rotated clockwise by 270°.

The factor not affecting the process may be different for each process. The method of the electronic device to transform the first input image 410 into the second input image 420 may depend on the factor not affecting the process.

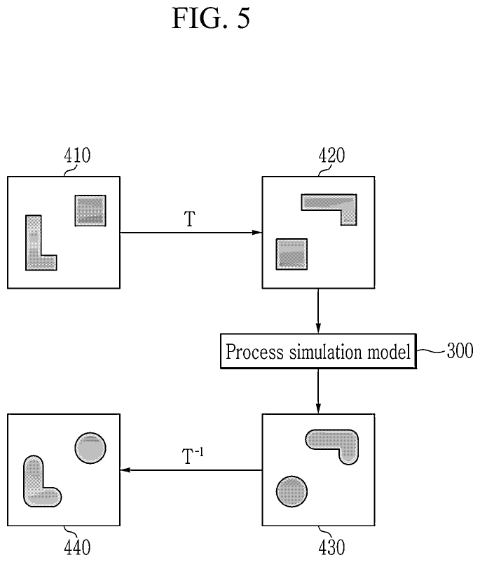

Hereinafter, the description describes a method of the electronic device to inversely transform the output image according to an example embodiment with reference to FIG. 5.

FIG. 5 is a diagram showing the method of the electronic device to inversely transform the output image according to an example embodiment. The electronic device according to an example embodiment may be the electronic device 100 of FIG. 1. The first input image 410 and the second input image 420, shown in FIG. 5, may correspond to the first input image 410 and the second input image 420, shown in FIG. 4, respectively.

Referring to FIG. 5, the electronic device may acquire the second input image 420 by transforming the first input image 410. The transformation from the first input image 410 to the second input image 420 may be referred to as ‘T’. For example, ‘T’ may be the movement of the pattern by −5 in the x-axis direction and +1 in the y-axis direction, flipped horizontally, and rotated clockwise by 270°. The electronic device may acquire the second input image 420 including the pattern included in the first input image 410 that is moved by −5 in the x-axis direction and +1 in the y-axis direction, flipped horizontally, and rotated clockwise by 270°.

The electronic device may acquire a second output image 430 by inputting the second input image 420 into the process simulation model 300. The electronic device may acquire an inversely transformed second output image 440 by inversely transforming the second output image 430. For example, the electronic device may reverse the transformation from the first input image 410 to the second input image 420 on the second output image 430. That is, the inverse transformation of the second output image 430 may be referred to as ‘T⁻¹’. For example, ‘T⁻¹’ may be rotated counterclockwise by 270°, flipped horizontally, and the movement of the pattern by +5 in the x-axis direction and −1 in the y-axis direction. The electronic device may acquire the inversely transformed second output image 440 including the pattern included in the second output image 430 that is rotated counterclockwise by 270°, flipped horizontally, and moved by +5 in the x-axis direction and −1 in the y-axis direction.

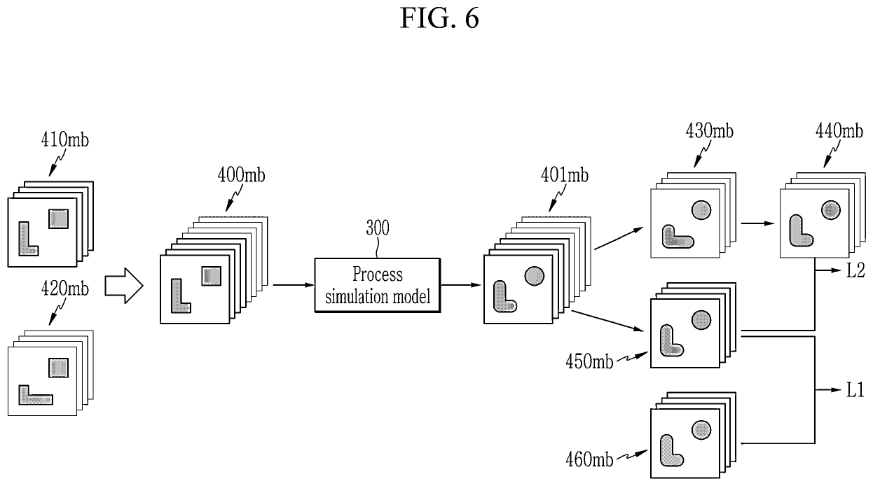

Hereinafter, the description describes a method of the electronic device to train the process simulation model according to an example embodiment with reference to FIG. 6.

FIG. 6 is a diagram showing the method of the electronic device to train the process simulation model according to an example embodiment. The electronic device according to an example embodiment may be the electronic device 100 of FIG. 1.

Referring to FIG. 6, the electronic device may generate the plurality of mini-batches by randomly sampling the pairs of the first and second input images 410 and 420 of in FIG. 4, the second input image 420 being transformed from the first input image 410. For example, the electronic device may generate m mini-batches of size n. For example, the electronic device may extract the n number of first input images 410 from the plurality of first input images 410, and extract the n number of second input images 420 corresponding to each of the n number of first input images 410 extracted from the plurality of the second input images 420. Hereinafter, the n number of extracted first input images 410 may be referred to as a first input mini-batch 410mb, and the n number of extracted second input images 420 corresponding thereto may be referred to as a second input mini-batch 420mb.

Hereinafter, the description describes a method of the electronic device to train the process simulation model for one mini-batch.

The electronic device may generate an input mini-batch 400mb, which is a pair of first and second input mini-batches 410mb and 420mb. The input mini-batch 400mb may include a total of 2n images. The electronic device may acquire an output mini-batch 401mb by inputting the input mini-batch 400mb into the process simulation model 300. The output mini-batch 401mb may include a first output mini-batch 450mb and a second output mini-batch 430mb. The first output mini-batch 450mb may correspond to the first input mini-batch 410mb, and include the n number of first output images. The second output mini-batch 430mb may correspond to the second input mini-batch 420mb, and include the n number of second output images.

The electronic device may acquire an inversely transformed second output mini-batch 440mb by inversely transforming the second output image of the second output mini-batch 430mb. The inversely transformed second output mini-batch 440mb may include the n number of inversely transformed second output images. The description already describes the method of the electronic device to inversely transform the second output image in detail with reference to FIG. 5, and thus omits its redundant description.

The electronic device may generate an actual mini-batch 460mb including the n number of images of the actual pattern corresponding to the n number of extracted first input images 410, respectively. The image of the actual pattern included in the actual mini-batch 460mb may be the n number of images acquired by augmenting the measured image of the actual pattern formed on the wafer on which the process is performed based on the design pattern. The electronic device may acquire the n number of images of the actual pattern corresponding to the n number of extracted first input images 410, respectively, by augmenting the measured image in the same way as the augmentation method of acquiring the n number of first input images 410 extracted from the image of the design pattern.

The electronic device may acquire the value of the first loss function L1 by comparing the first output mini-batch 450mb with the actual mini-batch 460mb. The electronic device may acquire the value of the first loss function L1 based on the difference between the n number of first output images included in the first output mini-batch 450mb and the n number of images of the actual pattern included in the corresponding actual mini-batch 460mb.

The electronic device may acquire the value of the second loss function L2 by comparing the first output mini-batch 450mb with the inversely transformed second output mini-batch 440mb. The electronic device may acquire the value of the second loss function L2 based on the difference between the n number of first output images included in the first output mini-batch 450mb and the n number of inversely transformed second output images corresponding thereto, respectively, and included in the inversely transformed second output mini-batch 440mb.

The electronic device may adjust the parameters of the process simulation model to reduce the values of the first loss function L1 and the second loss function L2. The electronic device may update the parameter of the process simulation model as the parameter for minimizing the sum of the values of the first loss function L1 and the second loss function L2. For example, the electronic device may update the parameter of the process simulation model 300 to have the parameter value for minimizing the sum of the value of the first loss function L1 multiplied by the ratio c1 corresponding to the first loss function L1 and the value of the second loss function L2 multiplied by the ratio c2 corresponding to the second loss function L2.

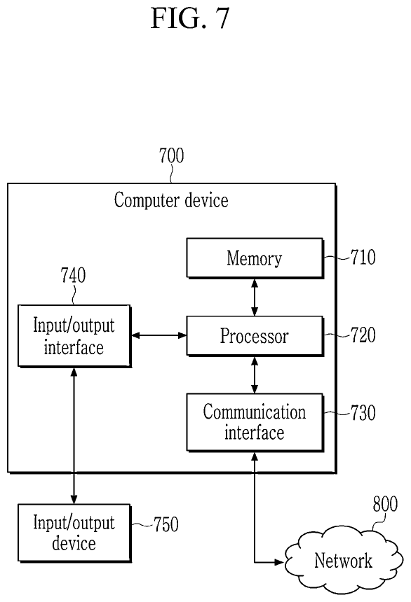

FIG. 7 is a diagram showing an example of a computer device implementing the electronic device according to an example embodiment. The electronic device 100 of FIG. 1 may be implemented by a computer device 700 shown in FIG. 7.

Referring to FIG. 7, the computer device 700 may include a memory 710, a processor 720, a communication interface 730, and an input/output interface 740.

The memory 710 is a computer-readable recording medium, and may include a random access memory (RAM), a read only memory (ROM), and a permanent mass storage device such as a disk drive. In addition, the memory 710 may store an operating system and at least one program code. These software components may be loaded into the memory 710 from the computer-readable recording medium separate from the memory 710. The separate computer-readable recording medium may include a computer-readable recording medium such as a hard disk, a flash memory, an optical disk, or an external hard disk. In addition, these software components may be loaded into the memory 710 through the communication interface 730.

The processor 720 may process an instruction of a computer program by performing basic arithmetic, logic, and input/output operations. The instruction may be provided to the processor 720 from the memory 710 or through the communication interface 730.

The communication interface 730 may provide a function for the computer device 700 to communicate with another device through a network 800. Here, a communication method of the communication interface 730 is not limited, and may include a short-distance wireless communication between devices as well as a communication method utilizing a communication network (e.g., mobile communication network, wired internet, wireless internet, or broadcasting network) which may be included in the network 800. For example, the network 800 may include at least one arbitrary network among networks such as a personal area network (PAN), a local area network (LAN), a campus area network (CAN), a metropolitan area network (MAN), a wide area network (WAN), a broadband network (BBN), and an internet. In addition, the network 800 may include at least one arbitrary network of a network topology including a bus network, a star network, a ring network, a mesh network, a star-bus network, a tree or hierarchical network, and is not limited thereto.

The input/output interface 740 may serve as an interface which may transmit a command/instruction or data, input from a user or an input/output device 750, to another component (or other components) of the computer device 700. In addition, the input/output interface 740 may output instructions or data, received from another component (or other components) of the computer device 700 to the user or the input/output device 750. For example, the input/output device 750 may include an input device such as a microphone, a keyboard, or a mouse, and the output device may include an output device such as a display or a speaker.

The example embodiments described above may be implemented in the form of the computer program that may be executed through various components on a computer, and such a computer program may be recorded on a computer-readable medium. Here, the medium may include a magnetic medium such as the hard disk, a floppy disk, or a magnetic tape, an optical recording medium such as a compact disk read only memory (CD-ROM) or a digital versatile disk (DVD), a magneto-optical medium such as a floptical disk, or a hardware device, such as the read only memory (ROM), the random access memory (RAM), or the flash memory, specifically configured to store and execute a program instruction.

The steps or operations may be performed in an appropriate order unless there is an explicit order or description to the contrary regarding the steps or operations configuring methods according to example embodiments. The present disclosure is not necessarily limited by an order of the steps or operations described above.

The use of any examples or example terms (for example, or the like) in the specification is intended only to describe the present disclosure in detail, and does not limit the scope of the present disclosure. In addition, those skilled in the art would appreciate that various modifications, combinations, and changes may be made within the scope of the patent claims or their equivalents.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although some example embodiments of the present disclosure have been described in detail hereinabove, the scope of the present disclosure is not limited thereto, and may include various modifications and alterations made by those skilled in the art and using basic concepts of the present disclosure as defined in the claims.

What is claimed is:

1. An electronic device comprising:
a memory configured to store instructions; and
processing circuitry configured to execute the instructions stored in the memory to cause the electronic device to
acquire a first input image based on an image of a design pattern to be formed on a wafer,
transform the first input image into a second input image based on a factor not affecting a process of manufacturing a semiconductor device, and
train a process simulation model by using a pair of the first input image and the second input image.

2. The electronic device of claim 1, wherein
the factor not affecting the process includes at least one of translation, rotation, or flip of the design pattern, and
the processing circuitry is configured to execute the instructions stored in the memory to further cause the electronic device to acquire the second input image by performing at least one transformation of the translation, the rotation, or the flip on a pattern included in the first input image.

3. The electronic device of claim 1, wherein
the processing circuitry is configured to execute the instructions stored in the memory to further cause the electronic device to acquire a pair of a first output image corresponding to the first input image and a second output image corresponding to the second input image by inputting the pair of the first and second input images into the process simulation model.

4. The electronic device of claim 3, wherein
the processing circuitry is configured to execute the instructions stored in the memory to further cause the electronic device to train the process simulation model based on a difference between the first output image and an image of an actual pattern formed on the wafer.

5. The electronic device of claim 4, wherein
the processing circuitry is configured to execute the instructions stored in the memory to further cause the electronic device to
inversely transform the second output image, and
train the process simulation model further based on a difference between the first output image and the inversely transformed second output image, and
the inverse transformation is reversing the transformation from the first input image to the second input image.

6. The electronic device of claim 4, wherein
the processing circuitry is configured to execute the instructions stored in the memory to further cause the electronic device to
acquire the first input image by augmenting the image of the design pattern, and
acquire the image of the actual pattern by augmenting an image acquired by measuring the wafer on which the process has been performed based on the design pattern.

7. The electronic device of claim 1, wherein
the processing circuitry is configured to execute the instructions stored in the memory to further cause the electronic device to
generate a plurality of mini-batches by randomly sampling a plurality of pairs of the first and second input images, and
train the process simulation model by using the plurality of mini-batches.

8. The electronic device of claim 1, wherein
the processing circuitry is configured to execute the instructions stored in the memory to further cause the electronic device to predict a process result based on the trained process simulation model.

9. An electronic device comprising:
a memory configured to store instructions; and
processing circuitry configured to execute the instructions stored in the memory to cause the electronic device to
acquire a first input image based on an image of a design pattern to be formed on a wafer,
transform the first input image into a second input image based on a factor not affecting a process of manufacturing a semiconductor device,
acquire a pair of output images by inputting a pair of the first input image and the second input image into a process simulation model, and
train the process simulation model to reduce a value of a first loss function based on a difference between one of the pair of output images and an image of an actual pattern formed on the wafer and a value of a second loss function based on a difference between the pair of the output images.

10. The electronic device of claim 9, wherein
the factor not affecting the process includes at least one of translation, rotation, or flip of the design pattern, and
the processing circuitry is configured to execute the instructions stored in the memory to further cause the electronic device to acquire the second input image by performing at least one transformation of the translation, the rotation, or the flip on a pattern included in the first input image.

11. The electronic device of claim 9, wherein
the processing circuitry is configured to execute the instructions stored in the memory to further cause the electronic device to
inversely transform the other of the pair of output images corresponding to the second input image to generate an inversely transformed output image, and
compare the inversely transformed output image with the one of the pair of output images corresponding to the first input image, and
the inverse transformation is reversing the transformation from the first input image to the second input image.

12. The electronic device of claim 9, wherein
the processing circuitry is configured to execute the instructions stored in the memory to further cause the electronic device to
generate a plurality of mini-batches by randomly sampling a plurality of pairs of the first and second input images, and
train the process simulation model by using the plurality of mini-batches.

13. A method of an operation of an electronic device, the method comprising:
acquiring a first input image based on an image of a design pattern to be formed on a wafer;
transforming the first input image into a second input image based on a factor not affecting a process of manufacturing a semiconductor device; and
training a process simulation model by using a pair of the first input image and the second input image.

14. The method of claim 13, wherein
the factor not affecting the process includes at least one of translation, rotation, or flip of the design pattern, and
the transforming of the first input image comprises performing at least one transformation of the translation, the rotation, or the flip on a pattern included in the first input image.

15. The method of claim 13, wherein
the training the process simulation model comprises acquiring a pair of a first output image corresponding to the first input image and a second output image corresponding to the second input image by inputting the pair of the first and second input images into the process simulation model.

16. The method of claim 15, wherein
the training the process simulation model comprises training the process simulation model based on a difference between the first output image and an image of an actual pattern formed on the wafer.

17. The method of claim 16, wherein
the training the process simulation model comprises
inversely transforming the second output image to generate an inversely transformed second output image, and
training the process simulation model further based on a difference between the first output image and the inversely transformed second output image, and
the inverse transformation is reversing the transformation from the first input image to the second input image.

18. The method of claim 16, wherein
the acquiring the first input image comprises augmenting the image of the design pattern, and
the method further comprises acquiring the image of the actual pattern by augmenting an image acquired by measuring the wafer on which the process has been performed based on the design pattern.

19. The method of claim 13, wherein
the training the process simulation model comprises
generating a plurality of mini-batches by randomly sampling a plurality of pairs of the first and second input images, and
performing the training using the plurality of mini-batches.

20. The method of claim 13, further comprising
predicting a process result based on the trained process simulation model.
